(19) United States
(12) Patent Application Publication
(10) Pub. No.: US 2025/0279372 A1
(43) Pub. Date: Sep. 4, 2025

(54) WAFER, WAFER DIE AND METHOD FOR MANUFACTURING WAFER DIE

(71) Applicant: Samsung Display Co., LTD., Yongin-si (KR)

(72) Inventors: Jae Yune CHANG, Yongin-si (KR); Jung Hwa PARK, Yongin-si (KR)

(73) Assignee: Samsung Display Co., LTD., Yongin-si (KR)

(21) Appl. No.: 18/903,585

(22) Filed: Oct. 1, 2024

(30) Foreign Application Priority Data
Mar. 4, 2024 (KR) 10-2024-0030554

(51) Int. Cl. H01L 23/544

(52) U.S. Cl. CPC H01L 23/544; H01L 2223/54493

(57) ABSTRACT

Wafer, a wafer die, and a method of manufacturing the wafer die are provided. a wafer includes a wafer substrate, an epitaxial thin film disposed on the wafer substrate and including a first semiconductor layer, an active layer, a second semiconductor layer, and a third semiconductor layer and a plurality of markers formed on the epitaxial thin film and indicating a crystal orientation.

CROSS-REFERENCE TO RELATED APPLICATION(S)

This application claims priority from Korean Patent Application No. 10-2024-0030554 under 35 § U.S.C. 119, filed on Mar. 4, 2024, in the Korean Intellectual Property Office, the entire contents of which are incorporated herein by reference.

### BACKGROUND

### 1. Technical Field

Embodiments relate to a wafer, a wafer die, and a method of manufacturing the wafer die.

### 2. Description of the Related Art

The importance of display devices is gradually increasing along with the development of multimedia. In response to this, various display devices such as liquid crystal display devices and light emitting display devices are being developed. Among these, light emitting display devices include display panels containing light emitting elements, and are applied to various types of electronic devices, including portable electronic devices and televisions, as well as virtual reality (VR) devices and augmented reality (AR) devices.

In case of manufacturing epitaxial wafers used in such display devices, a plurality of semiconductor layers are grown. Since defects in the plurality of semiconductor layers grown may cause abnormalities in the light emitting element formed by subsequent processes, inspection or analysis of the wafers is performed prior to subsequent processes. This inspection or analysis may be considered an essential process.

To describe these analysis and verification steps, first, a specimen is prepared by cutting a predetermined size from the wafer, and then the specimen is inspected or analyzed through a device such as a transmission electron microscope (TEM).

### SUMMARY

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment, a wafer may include a wafer substrate, an epitaxial thin film disposed on the wafer substrate and including a first semiconductor layer, an active layer, a second semiconductor layer, and a third semiconductor layer and a plurality of markers formed on the epitaxial thin film and indicating a crystal orientation.

The plurality of markers may be made of a photosensitive polymer.

The plurality of markers may be disposed on a surface of the epitaxial thin film and spaced apart from neighboring markers by a first distance.

The first distance may be in a range of about 50 μm and about 300 μm.

The plurality of markers may be arranged in tens to hundreds per unit area of about 1 cm×1 cm of the epitaxial thin film.

The plurality of markers may have a thickness of about 500 nm to about 1 μm.

Each of the plurality of markers may indicate a crystal orientation by a plurality of strokes and a contact point of each stroke.

A length of each of the plurality of strokes may range from about 500 nm to about 1 μm.

The plurality of markers may have a same shape.

The wafer substrate may include at least one of a flat zone and a notch, wherein a crystal orientation indicated by the flat zone or notch may be consistent with a crystal orientation indicated by the plurality of markers.

A wafer may include a wafer substrate, an epitaxial thin film disposed on the wafer substrate and including a first semiconductor layer, an active layer, a second semiconductor layer, and a third semiconductor layer and a plurality of markers formed between the wafer substrate and the epitaxial thin film and indicating a crystal orientation.

A wafer die may include a wafer substrate cut to a first size, an epitaxial thin film disposed on the wafer substrate and including a first semiconductor layer, an active layer, a second semiconductor layer, and a third semiconductor layer, and a plurality of markers formed on the epitaxial thin film and indicating a crystal orientation.

The first size may be about 1 cm×1 cm in width×height.

Tens to hundreds of the plurality of markers may be disposed on a surface of the epitaxial thin film.

Each of the plurality of markers may indicate a crystal orientation by a plurality of strokes and a contact point of each stroke.

According to an embodiment, a wafer die may include a wafer substrate cut to a first size, an epitaxial thin film disposed on the wafer substrate and including a first semiconductor layer, an active layer, a second semiconductor layer, and a third semiconductor layer and a plurality of markers formed between the wafer substrate and the epitaxial thin film and indicating a crystal orientation.

According to an embodiment, a method of manufacturing wafer die may include growing an epitaxial thin film including a first semiconductor layer, an active layer, a second semiconductor layer, and a third semiconductor layer on a wafer substrate to form an epitaxial wafer, the forming a plurality of markers indicating a crystal orientation on the epitaxial thin film and the dividing the epitaxial wafer into a plurality of wafer dies, wherein each of the wafer dies may include the plurality of markers.

The forming of the plurality of markers indicating the crystal orientation may include forming a photoresist layer by uniformly applying a photosensitive polymer over the epitaxial thin film and the forming of the plurality of markers by selectively etching the photoresist layer using a mask pattern.

The dividing the epitaxial wafer into a plurality of wafer dies may include dicing the epitaxial wafer to be divided into a plurality of wafer dies having a first size.

The first size may be about 1 cm×1 cm in width×height.

Aspects and features of embodiments are to provide a wafer, a wafer die, and a method of manufacturing the wafer die that may confirm the crystal orientation on a diced wafer.

According to embodiments, the crystal orientation may be confirmed on the diced wafer die by forming a plurality of markers indicating the crystal orientation on the epitaxial thin film.

However, the effects of the present disclosure are not limited to the aforementioned effects, and various other effects are included in the present specification.

### BRIEF DESCRIPTION OF THE DRAWINGS

FIG. 1 is a schematic perspective view illustrating an epitaxial wafer.

FIG. 2 is a schematic plan view illustrating an epitaxial wafer.

FIG. 3 is an enlarged schematic cross-sectional view illustrating a portion of an epitaxial wafer.

FIGS. 4 to 6 are schematic plan views illustrating an example of a marker.

FIG. 7 is an enlarged schematic cross-sectional view illustrating a portion of an epitaxial wafer according to another embodiment.

FIG. 8 is a schematic perspective view of a schematic shape of a wafer die.

FIG. 9 is an enlarged schematic plan view of area A of FIG. 8.

FIG. 10 is a schematic cross-sectional view of FIG. 9 according to an embodiment.

FIG. 11 is a schematic cross-sectional view of FIG. 9 according to another embodiment.

FIG. 12 is a schematic flow chart illustrating a method of manufacturing a wafer die according to an embodiment.

FIGS. 13 to 17 are schematic diagrams to illustrate a method of manufacturing a wafer die according to an embodiment.

FIG. 18 is an example of a structural analysis image obtained by a specimen manufactured in a crystal orientation.

FIG. 19 is an example of a structural analysis image obtained by a specimen manufactured in a non-crystal orientation.

FIGS. 20 to 24 are schematic diagrams to illustrate a method of manufacturing light emitting elements.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently according to the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the certain value as determined by one of ordinary skill in the art, considering the measurement in question and the error associated with measurement of the certain quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

In this specification, crystal orientation refers to how the crystal structure is composed. Materials with a crystal structure, such as sapphire, may have different properties for a given orientation. A property may be one or more of electrical, optical, or mechanical properties. For example, crystal orientation refers to the alignment of the crystallographic axes of the wafer material relative to the wafer surface and edges. Further, a crystal plane refers to a flat, two-dimensional surface within the crystalline structure of the wafer material, defined by the periodic arrangement of atoms.

Therefore, crystal orientation plays an important role in the process of manufacturing and processing devices. In case of manufacturing a device, the characteristics of the device may be optimized by considering the crystal orientation, and in case of processing the device, it may be processed differently according to the crystal orientation.

Hereinafter, specific embodiments will be described with reference to the attached drawings.

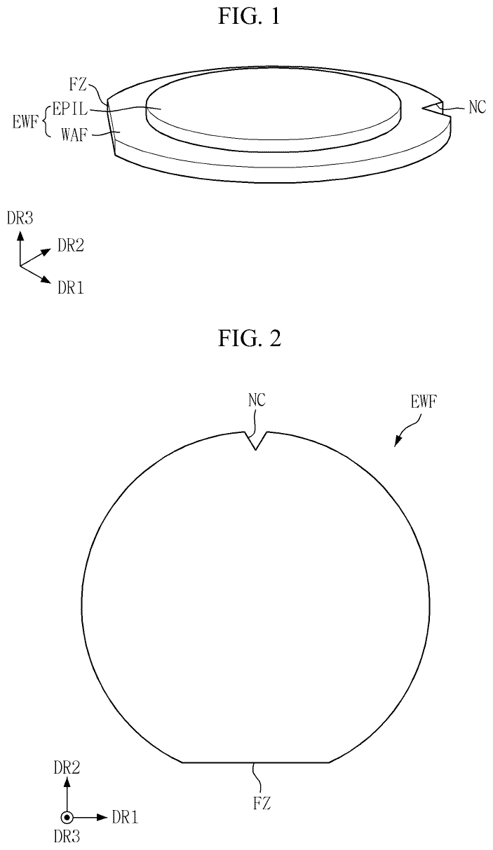

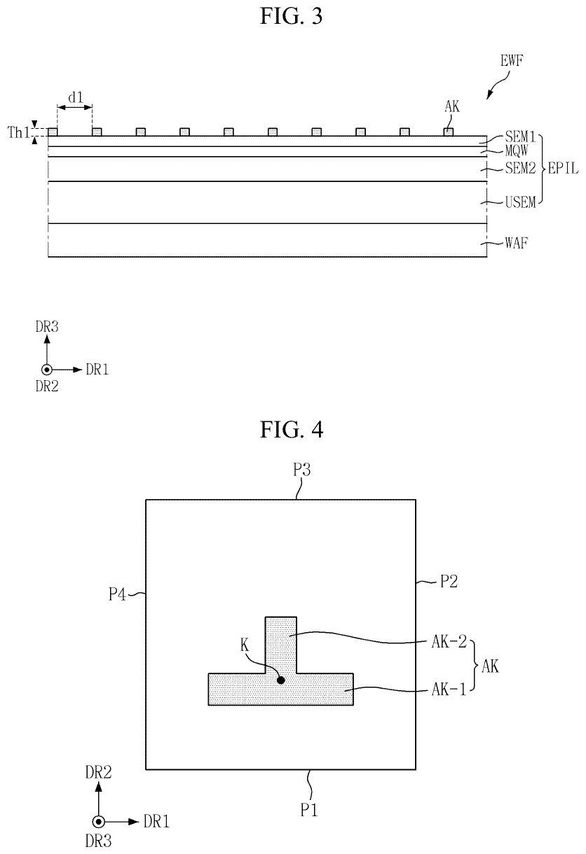

FIG. 1 is a schematic perspective view illustrating an epitaxial wafer. FIG. 2 is a schematic plan view illustrating an epitaxial wafer. FIG. 3 is an enlarged schematic cross-sectional view illustrating a portion of an epitaxial wafer.

Referring to FIGS. 1 to 3, an epitaxial wafer EWF may include a wafer substrate WAF, an epitaxial thin film EPIL disposed on the wafer substrate WAF, and markers AK.

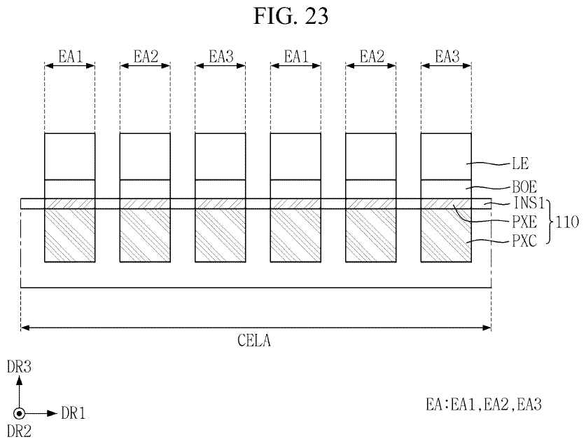

The wafer substrate WAF may be a semiconductor substrate suitable for epitaxial growth of a semiconductor. For example, the wafer substrate WAF may be a substrate containing a material such as silicon (Si), sapphire, SiC, GaN, GaAs, or ZnO. In case that epitaxial growth for manufacturing a light emitting element (e.g., LE in FIG. 23) may be performed smoothly, the type, material, and shape of the wafer substrate WAF are not limited.

The wafer substrate WAF may include at least one of a flat zone FZ or a notch NC that indicates the crystal orientation of the wafer.

The flat zone FZ may be an area where the crystal plane of the wafer is flat. The notch NC may be a triangular groove that indicates the crystal orientation of the wafer. In another example, an alignment marker may be used instead of the flat zone FZ or the notch NC.

In an embodiment, the wafer substrate WAF may be about 8 inches, about 10 inches, or about 12 inches in diameter. The wafer substrate WAF may be several to hundreds of micrometers (μm). Each length (or width) of the wafer substrate WAF in a third direction DR3 may be about 100 μm or less. The third direction DR3 may intersect each of a first direction DR1 and a second direction DR2, and a normal line direction of a surface (e.g., upper or lower surface) of the wafer substrate WAF may be substantially parallel to the third direction DR3.

The epitaxial thin film EPIL may include a third semiconductor layer USEM, a second semiconductor layer SEM2, an active layer MQW, and a first semiconductor layer SEM1 sequentially disposed and/or stacked along the third direction DR3 on the wafer substrate WAF.

The epitaxial thin film EPIL may further include additional layers according to embodiments. For example, the epitaxial thin film EPIL may further include a superlattice layer disposed between the active layer MQW and the second semiconductor layer SEM2 and/or an electronic blocking layer disposed between the first semiconductor layer SEM1 and the active layer MQW, and/or the like.

The third semiconductor layer USEM may be disposed to reduce the difference in lattice constant between the second semiconductor layer SEM2 and the wafer substrate WAF. In an example, the third semiconductor layer USEM may include an undoped semiconductor, which is an n-type or p-type undoped material. In an embodiment, the third semiconductor layer USEM may include a nitride-based semiconductor material or a phosphide-based semiconductor material. For example, the third semiconductor layer USEM may include a nitride-based semiconductor material, including at least one of GaN, AlGaN, InGaN, AlInGaN, AlN, and InN, or a phosphide-based semiconductor material, including at least one of GaP, GaInP, AlGaP, AlGaInP, AlP, and InP. The third semiconductor layer USEM may include a material other than silver.

The second semiconductor layer SEM2 may be disposed on the active layer MQW. In an embodiment, the second semiconductor layer SEM2 may include a nitride-based semiconductor material or a phosphide-based semiconductor material. For example, the second semiconductor layer SEM2 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The second semiconductor layer SEM2 may include other materials.

The second semiconductor layer SEM2 may include a semiconductor material doped with a second conductivity type dopant. For example, the second semiconductor layer SEM2 may be made of GaN (e.g., n-GaN) doped with a second conductivity type dopant (e.g., n-type dopant) such as Si, Ge, Sn, etc.

The active layer MQW may be disposed on the first semiconductor layer SEM1. The active layer MQW may emit light by recombination of electron-hole pairs in response to an electrical signal applied through the first semiconductor layer SEM1 and the second semiconductor layer SEM2. For example, the active layer MQW may be a light emitting layer of the light emitting element LE.

The active layer MQW may include a material with a single quantum well structure or a multiple quantum well structure. In case that the active layer MQW includes a material with a multi-quantum well structure, the active layer MQW may have a structure in which well layers and barrier layers are alternately stacked. The active layer MQW may include other group III-V semiconductor materials according to the wavelength of emitted light.

In an embodiment, the active layer MQW may include a nitride-based semiconductor material or a phosphide-based semiconductor material. For example, the active layer MQW may include a nitride-based semiconductor material including at least one of GaN, AlGaN, InGaN, InGaAlN, AlN, InN, and AlInN, or a phosphide-based semiconductor material including at least one of GaP, GaInP, AlGaP, AlGaInP, AlP, and InP. For example, the well layer may be formed of InGaN, and the barrier layer may be formed of GaN or AlGaN, but embodiments are not limited thereto. In case that the active layer MQW includes InGaN, the color of light emitted from the light emitting element LE may be controlled by adjusting the content of indium (In). The active layer MQW may also include other materials.

The first semiconductor layer SEM1 may be disposed on the active layer MQW. The first semiconductor layer SEM1 may include a nitride-based semiconductor material or a phosphide-based semiconductor material. For example, the first semiconductor layer SEM1 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The first semiconductor layer SEM1 may also include other materials.

The first semiconductor layer SEM1 may include a semiconductor material doped with a first conductivity type dopant. For example, the first semiconductor layer SEM1 may include GaN (e.g., p-type dopant) doped with a first conductive dopant (e.g., p-type dopant), such as Mg, Zn, Ca, Se, Ba, etc.

In an embodiment, the first semiconductor layer SEM1 and the second semiconductor layer SEM2 may have different thicknesses in a thickness direction (e.g., third direction DR3) of the epitaxial thin film EPIL. For example, the second semiconductor layer SEM2 may have a greater thickness than the first semiconductor layer SEM1 in the thickness direction of the epitaxial thin film EPIL.

Markers AK may be disposed on the epitaxial thin film EPIL to indicate the crystal orientation.

The markers AK may be disposed in a first size at a first distance dl on the entire surface of the epitaxial thin film EPIL. For example, the range of the first distance d1 may be in a range of about 50 μm to about 300 μm, and in an embodiment, the markers AK may be disposed (or spaced) at an interval of about 100 μm. Accordingly, the markers AK may be disposed in tens to hundreds per unit area of about 1 cm×1 cm on the wafer thin film EPIL. The first size may be about 1 μm×1 μm (width×height), but embodiments are not limited thereto. The smaller the marker AK, the better, but it should not be less than a size that is confirmed with an electron microscope.

The thickness Th1 of the markers AK may be equal to or less than the horizontal length (e.g., in the first direction DR1) and the vertical length (e.g., in the second direction DR2) of the marker AK. For example, the thickness Th1 of the markers AK may be in a range of about 500 nm to about 1 μm.

The markers AK may be made of a photosensitive polymer (e.g., photoresist). The markers AK may all have the same shape and point in the crystal orientation.

Next, the shape of the marker AK will be described with reference to FIGS. 4 to 6.

FIGS. 4 to 6 are schematic plan views illustrating an example of a marker AK.

Referring to FIG. 4, the marker AK, which is in an area defined by P1, P2, P3, and P4, may be formed of two or more strokes. For example, the marker AK may include a first stroke AK-1 and a second stroke AK-2, the first stroke AK-1 may be disposed horizontally with the crystal plane, and the second stroke AK-2 may be disposed perpendicular to the first stroke AK-1, but the position of the contact point K of the second stroke AK-2 and the first stroke AK-1 may indicate the crystal plane. For example, in FIG. 4, in case that P1 is the crystal plane, it is difficult to determine whether the crystal plane is P1 or P3 in case that only the first stroke AK-1 is placed horizontal to the crystal plane. Therefore, the direction of the contact point in the second stroke AK-2 may be the direction of the crystal plane by arranging the second stroke AK-2 in perpendicular contact with the first stroke AK-1. For example, the marker AK may clearly indicate the crystal orientation through the second stroke AK-2 and the first stroke AK-1.

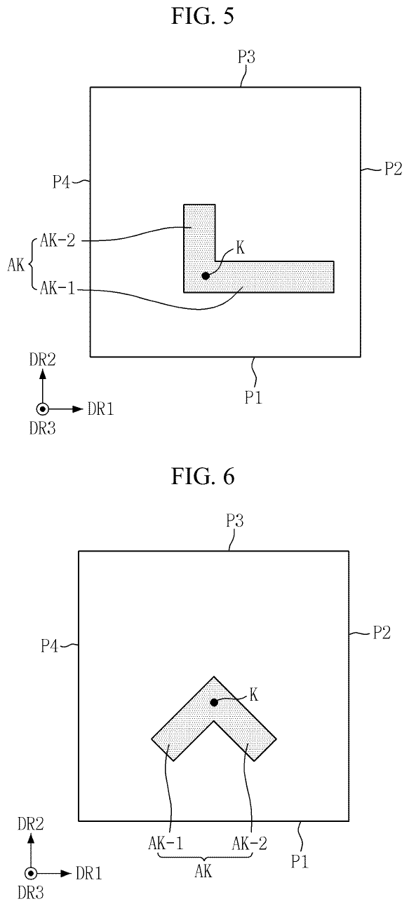

Referring to FIG. 5, the first stroke AK-1 may be arranged to be longer than the second stroke AK-2. By this arrangement, the direction in which the second stroke AK-2 points to the contact point K while being horizontal to the longer first stroke AK-1 may be the crystal plane.

Referring to FIG. 6, the first stroke AK-1 and the second stroke AK-2 contact each other at a single point and may be arranged similarly to the notch NC.

The first stroke AK-1, the second stroke AK-2, and the contact point K may be formed to point in the same direction as the notch NC and may point in the same direction of the crystal plane as the notch NC.

In FIGS. 4 and 6, the marker AK may be made up of at least two tangentially adjacent sections, and the direction of the crystal plane may be accurately indicated through each stroke and contact point.

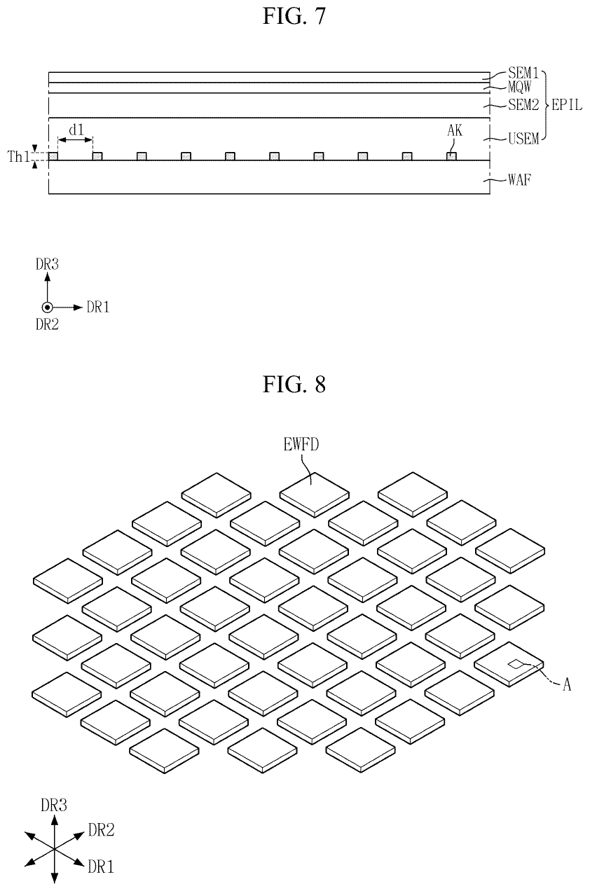

FIG. 7 is an enlarged schematic cross-sectional view illustrating a portion of an epitaxial wafer according to another embodiment.

Referring to FIG. 7, it may be different from FIG. 3 in that the marker AK is disposed between the wafer substrate WAF and the epitaxial thin film EPIL.

The marker AK may be disposed on the wafer substrate WAF, and an epitaxial thin film EPIL may be disposed on the marker AK. For example, the marker AK may be disposed (e.g., directly disposed) on the wafer substrate WAF, and the third semiconductor layer USEM may be disposed (e.g., directly disposed) on the marker AK. The third semiconductor layer USEM may be formed with a groove corresponding to the marker AK. For example, the marker AK may be surrounded on both the side and top surfaces by the third semiconductor layer USEM.

In case that the marker AK is disposed between the wafer substrate WAF and the epitaxial thin film EPIL, there is a disadvantage of poor visibility. However, there is an advantage that the marker AK may be removed together in case that the third semiconductor layer USEM is removed by a method such as gliding.

For example, the epitaxial wafer EWF may be divided into small sizes through a dicing process. Each of the divided pieces may be called a wafer die.

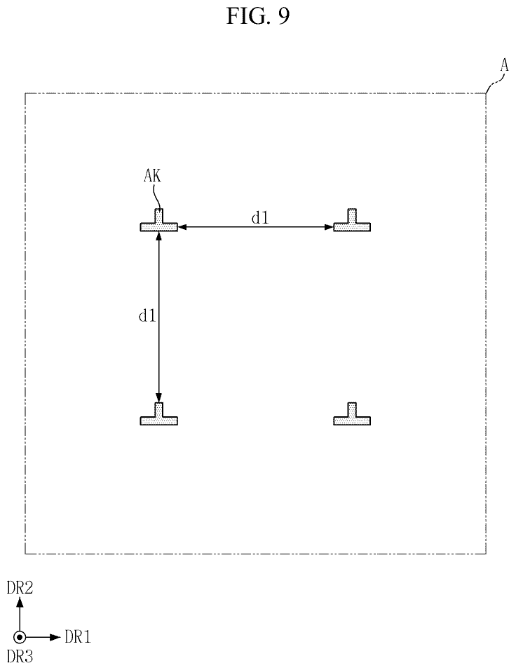

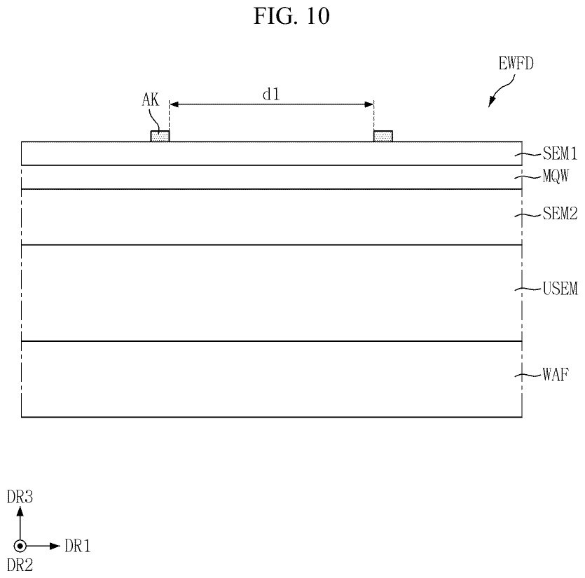

FIG. 8 is a schematic perspective view of a schematic shape of a wafer die. FIG. 9 is an enlarged schematic plan view of area A of FIG. 8. FIG. 10 is a schematic cross-sectional view of FIG. 9 according to an embodiment.

Referring to FIGS. 8 to 10, the wafer dies EWFD may be smaller sized pieces divided from the epitaxial wafer (EWF in FIG. 1), and the cross-sectional structure (or shape) of which is substantially the same as the cross-sectional structure (or shape) of the epitaxial wafer EWF. For example, each of the wafer dies EWFD may include a wafer substrate divided into smaller sizes (e.g., a piece of the wafer substrate WAF in FIG. 3), an epitaxial thin film EPIL divided into smaller sizes, and markers AK.

In an embodiment, each of the wafer dies EWFD may have a size (e.g., an area corresponding to an area of each cell region) corresponding to an area of a backplane substrate (e.g., a backplane mother substrate to be divided into the backplane substrate of each display panel) including cell regions for forming display panels. For example, by dividing the epitaxial wafer EWF into a size corresponding to the area of each cell region of a backplane substrate including cell regions, wafer dies EWFD of a size corresponding to an area of each cell region may be manufactured. In an embodiment, each of the wafer dies EWFD may have a size greater than or equal to the area of the display area positioned in each cell region.

In an embodiment, each of the wafer dies EWFD may be rectangular or square. The wafer die EWFD may have a size of about 1 cm×1 cm, but embodiments are not limited thereto.

Although the markers AK are not visible to the naked eye, tens to hundreds of markers may be disposed on each of the wafer dies EWFD. The markers AK may be arranged in rows and columns at a first distance (or first interval). The distance between neighboring markers AK may be the first distance. For example, the range of the first distance d1 may be 50 μm to 300 μm, and in an embodiment, the first distance d1 may be about 100 μm.

In FIGS. 8 to 10, each of the divided wafer dies EWFD may include a marker AK. Therefore, the crystal orientation may be confirmed through the marker AK independently without the need for crystal orientation information of the epitaxial wafer EWF, which functions as the ledger of the wafer die EWFD.

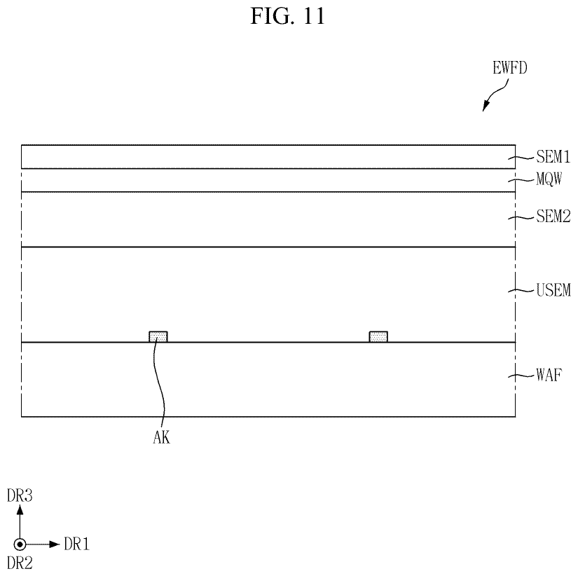

FIG. 11 is a schematic cross-sectional view of FIG. 9 according to another embodiment.

Referring to FIG. 11, it may be different from FIG. 10 in that the marker AK is disposed between the wafer substrate WAF and the epitaxial thin film EPIL.

The marker AK may be disposed on the wafer substrate WAF, and the epitaxial thin film EPIL may be disposed on the marker AK. For example, the marker AK may be disposed (e.g., directly disposed) on the wafer substrate WAF, and the third semiconductor layer USEM may be disposed (e.g., directly disposed) on the marker AK.

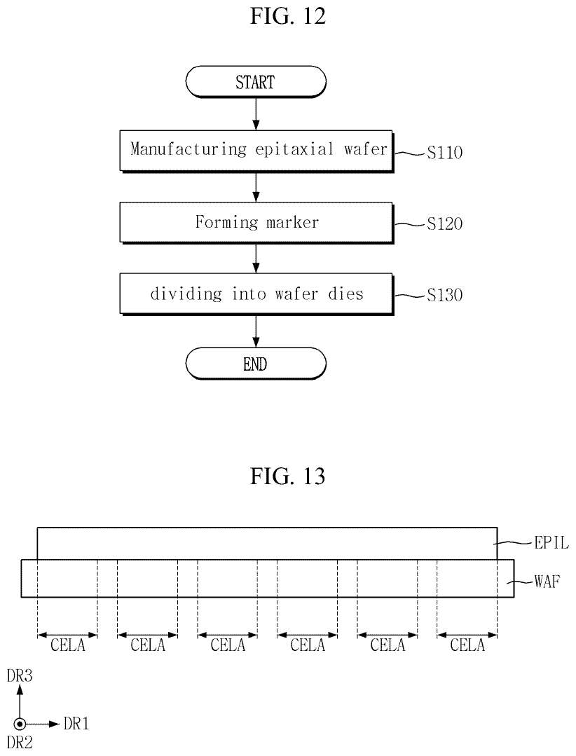

FIG. 12 is a flow chart illustrating a method of manufacturing a wafer die according to an embodiment. FIGS. 13 to 17 are schematic diagrams to illustrate a method of manufacturing a wafer die according to an embodiment.

For example, FIGS. 13 to 17 each illustrate specific steps for forming a wafer die EWFD in the form of a schematic perspective view, schematic cross-sectional view, or schematic plan view.

Referring to FIGS. 12 and 13, an epitaxial wafer EWF including an epitaxial thin film EPIL may be manufactured. (S110 in FIG. 12)

For example, a wafer substrate WAF (or another type of substrate suitable for epitaxial growth) may be prepared as shown in FIG. 12, and an epitaxial thin film EPIL may be formed on the wafer substrate WAF. FIG. 12 illustrates a schematic cross-sectional view of a portion of an epitaxial wafer EWF according to an embodiment.

The wafer substrate WAF may include areas (or cell regions) CELA corresponding to wafer dies EWFD in case of performing a subsequent dicing process, etc.

For example, on a wafer substrate WAF, a third semiconductor layer USEM, a second semiconductor layer SEM2, an active layer MQW, and a first semiconductor layer SEM1 may be sequentially formed through epitaxial growth. In an embodiment, the third semiconductor layer USEM, the second semiconductor layer SEM2, the active layer MQW, and the first semiconductor layer SEM1 may be formed by epitaxial growth utilizing a process technology such as metal-organic chemical vapor deposition (MOCVD), metal-organic vapor phase epitaxy (MOVPE), molecular beam epitaxy (MBE), liquid phase epitaxy (LPE), or vapor phase epitaxy (VPE).

The third semiconductor layer USEM may be formed of the material of the previously explained third semiconductor layer USEM. For example, the third semiconductor layer USEM may be formed of at least one nitride-based semiconductor material or phosphide-based semiconductor material and may be formed of a single layer or multiple semiconductor layers. The third semiconductor layer USEM may be doped to include a second conductivity type dopant (e.g., an n-type dopant).

The third semiconductor layer USEM may include an undoped semiconductor, which is an n-type undoped material or a p-type undoped material.

The second semiconductor layer SEM2 may be formed of the material of the previously explained second semiconductor layer SEM2. For example, the second semiconductor layer SEM2 may be formed of at least one nitride-based semiconductor material or phosphide-based semiconductor material and may be formed as a single layer or multiple semiconductor layers. The second semiconductor layer SEM2 may be doped to include a second conductivity type dopant (e.g., an n-type dopant).

The active layer MQW may be formed of the material of the previously explained active layer MQW. For example, the active layer MQW may be formed of at least one nitride-based semiconductor material or phosphide-based semiconductor material. In an embodiment, a barrier layer and a quantum well layer may be alternately and/or repeatedly formed on the second semiconductor layer SEM2 to form an active layer MQW having a multi-quantum well structure.

The first semiconductor layer SEM1 may be formed of the material of the previously explained first semiconductor layer SEM1. For example, the first semiconductor layer SEM1 may be formed of a single nitride-based semiconductor material or a phosphide-based semiconductor material or may be formed of a single layer or multiple semiconductor layers. The first semiconductor layer SEM1 may be doped to include a first conductivity type dopant (e.g., a p-type dopant).

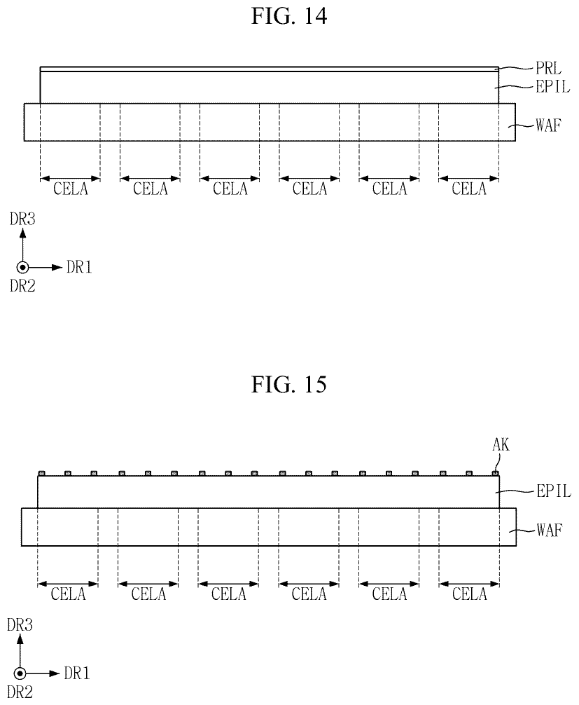

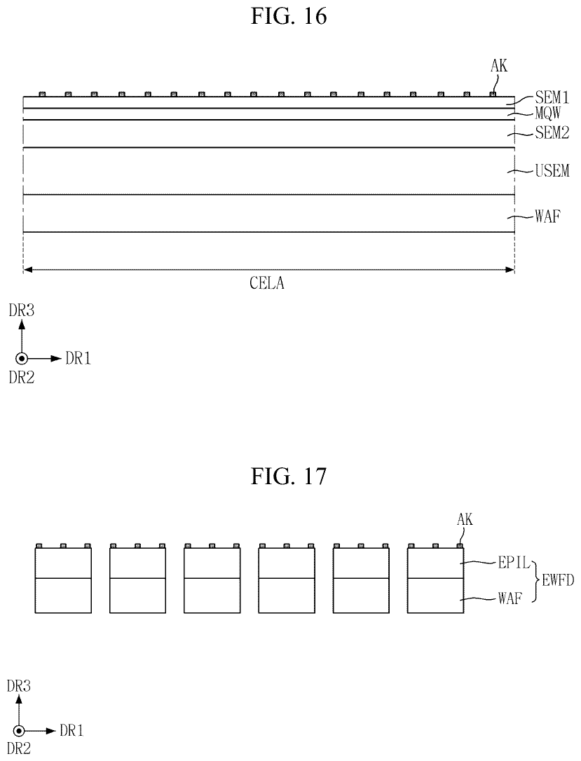

Referring to FIGS. 12 and 14 to 16, markers AK may be formed on the epitaxial thin film EPIL (S120 in FIG. 12). FIG. 15 is an enlarged schematic cross-sectional view of a portion of the cross-section of FIG. 14.

For example, referring to FIG. 13, a photoresist layer PRL may be formed by uniformly applying a photosensitive polymer (e.g., photoresist) to the entire surface of the epitaxial thin film EPIL. The thickness of the photoresist layer PRL may be about 500 nm to about 1 μm.

Referring to FIGS. 14 and 15, the photoresist layer PRL may be selectively etched to form the marker AK.

For example, in case that the photosensitive polymer (e.g., photoresist) is negative, a mask containing a marker pattern may be placed on the photoresist layer PRL and a photo process may be performed to selectively etch the portions not exposed by the mask. The photoresist in the exposed portion becomes the marker AK. In another example, in case that the photosensitive polymer (e.g., photoresist) is positive, a mask containing a marker pattern may be placed on the photoresist layer PRL and a photo process may be performed to selectively etch the portion exposed by the mask. For example, the unexposed photoresist may become the marker AK. The marker pattern may have a pattern that is repeated at a first distance d1. Accordingly, the marker may be formed at a first distance d1. The range of the first distance d1 may be about 50 μm to about 300 μm, and in an embodiment, the first distance d1 may be about 100 μm. The size of the marker may be about 1 μm×1 μm (width×height), but embodiments are not limited thereto.

Referring to FIGS. 12 and 17, the epitaxial wafer EWF may be divided into wafer dies EWFD (S130 in FIG. 12). In an example, wafer dies EWFD may be manufactured by dicing the epitaxial wafer EWF to a size corresponding to the area of the areas (or cell regions) CELA corresponding to the wafer dies EWFD.

The size of the wafer dies EWFD may be greater than a first distance d1, which is the spacing distance between the markers AK and may be formed such that tens or hundreds of markers AK are disposed within the wafer dies EWFD. For example, the size of wafer dies EWFD may be about 1 cm×1 cm.

The wafer dies EWFD manufactured with reference to FIGS. 12 to 17 may correspond to the wafer dies EWFD described with reference to FIGS. 8 to 10. For example, the wafer dies EWFD may include a wafer substrate WAF, an epitaxial thin film EPIL, and markers AK. The markers AK may be disposed on the lower surface or the upper surface of the epitaxial thin film EPIL.

In an embodiment, after dividing the epitaxial wafer EWF into wafer dies EWFD, the evaluation (e.g., quality test) for each wafer die EWFD may be performed to select good products. The wafer dies EWFD selected as good products may be used to form light emitting elements LE in each cell region CELA by a subsequent process.

In an embodiment, the wafer dies EWFD may be subjected to destructive analysis for evaluation. The destructive analysis may require fabrication of a specimen. For example, the crystal orientation of the wafer dies EWFD must be confirmed first to manufacture a specimen.

Since the wafer dies EWFD according to an embodiment include a marker AK indicating the crystal orientation, it is easy to check the crystal orientation of the wafer dies EWFD in case of manufacturing the specimen.

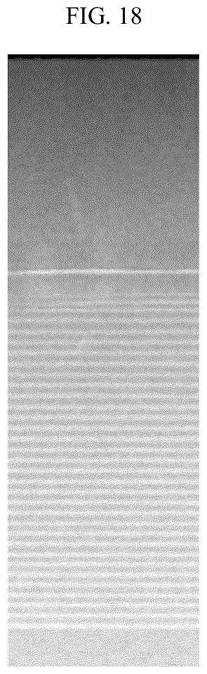

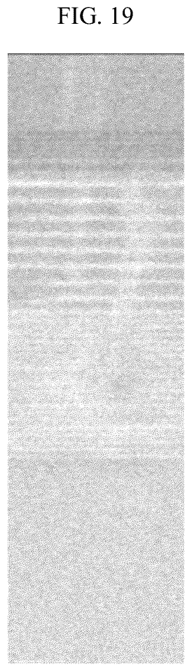

FIG. 18 is an example of a structural analysis image obtained by a specimen manufactured in a crystalline orientation. FIG. 19 is an example of a structural analysis image obtained by a specimen manufactured in a non-crystalline orientation.

For example, the structural analysis images may be acquired by a transmission electron microscope (TEM).

Referring to FIGS. 18 and 19, the structural analysis image acquired by a specimen manufactured in a crystal orientation may be of higher quality than the structural analysis image acquired by a specimen manufactured in a non-crystal orientation. It is possible to measure thickness at the atomic level through the structural analysis images acquired from specimens manufactured in the crystal orientation, and measurement errors may be relatively small due to clear images. On the other hand, structural analysis images acquired by non-crystal orientation specimens have low atomic resolution, which makes it difficult to measure atomic thickness, and in case that atomic thickness is measured, the measurement error may be relatively large. In case that the thickness is measured in atomic units, the measurement error may be relatively large.

In case that it is difficult to confirm the crystal orientation in the wafer dies EWFD, a specimen may be manufactured with the non-crystal orientation. In case that the specimen is manufactured in the non-crystal orientation, the analysis quality may deteriorate.

In case that the wafer dies EWFD have a marker AK, as in an embodiment, it may be easy to identify the crystal orientation, which facilitates the manufacture of specimens in the crystal orientation.

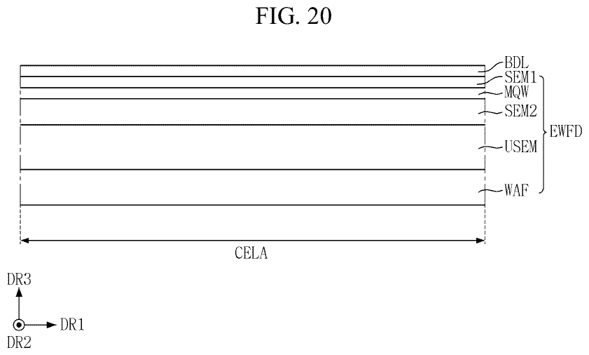

Hereinafter, with reference to FIGS. 20 to 24, a method of manufacturing light emitting elements LE using wafer dies EWFD by a subsequent process will be described.

FIGS. 20 to 24 are schematic diagrams to illustrate a method of manufacturing light emitting elements. The wafer dies EWFD described with reference to FIGS. 20 to 24 may correspond to the wafer dies EWFD described with reference to FIGS. 12 to 17.

For example, referring to FIG. 20, the marker formed of photoresist (AK in FIG. 17) may be removed by a method such as stripping or ashing, and a bonding material may be applied on the epitaxial thin film EPIL.

For example, a conductive bonding layer BDL may be formed by applying (e.g., entirely applying) a conductive bonding material on the epitaxial thin film EPIL. For example, gold (Au), copper (Cu), aluminum (Al), tin (Sn), or other bonding metals may be applied (e.g., deposited) on the top surface of the epitaxial thin film EPIL to form the conductive bonding layer BDL.

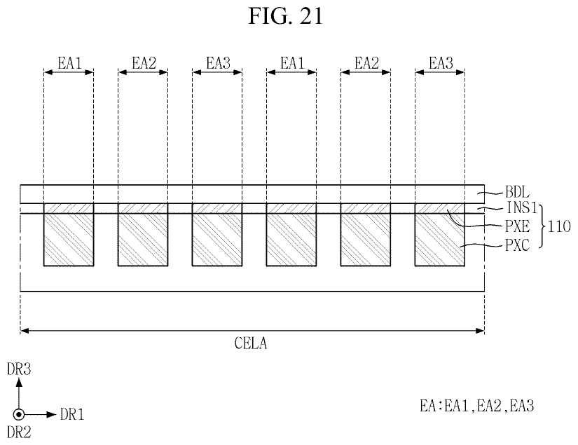

Referring to FIG. 21, a backplane substrate 110 including a conductive bonding layer BDL may be prepared.

For example, the backplane substrate 110 may include light emitting areas EA (e.g., EA1, EA2, and EA3) in which light emitting elements LE will be formed. The backplane substrate 110 may include pixel electrodes PXE provided in the light emitting areas EA. For example, the backplane substrate 110 may include pixel electrodes PXE individually provided in the light emitting areas EA of each cell region CELA, pixel circuits PXC connected to each pixel electrode PXE, a first insulating layer INS1 disposed around the periphery of the pixel electrodes PXEs, and a conductive bonding layer BDL disposed on the pixel electrodes PXE and the first insulating layer INS1.

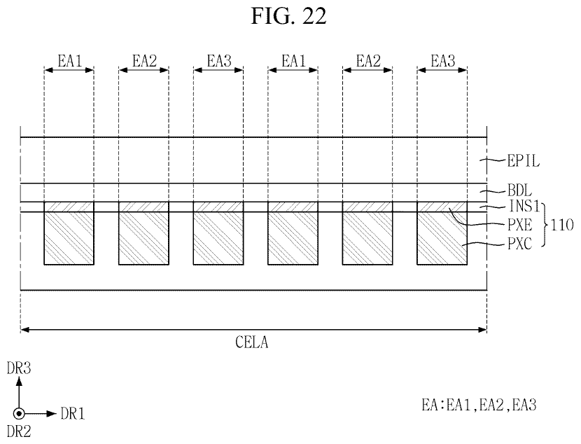

Referring to FIG. 22, a wafer die (EWFD in FIG. 20) may be bonded on the backplane substrate 110.

For example, the conductive bonding layer BDL of the backplane substrate 110 and the conductive bonding layer BDL of the wafer dies EWFD may be arranged to face each other, and the conductive bonding layer BDL can be bonded by a thermal compression (TC) bonding method. The conductive bonding layer BDL of the backplane substrate 110 and the conductive bonding layer BDL of the epitaxial dies EPID may be fused to form an integrated conductive bonding layer BDL.

Accordingly, the backplane substrate 110 and the wafer dies EWFD may be bonded. Subsequently, the wafer substrate WAF of the wafer dies EWFD may be removed.

The wafer substrate WAF may be removed by a laser lift off (LLO) method, but embodiments are not limited thereto.

Referring to FIG. 23, light emitting elements LE may be formed.

For example, the epitaxial thin film EPIL may be etched to form each light emitting element LE in the light emitting areas EA. The light emitting elements LE may be formed on pixel electrodes PXE positioned in each light emitting area EA.

For example, the conductive bonding layer BDL may be etched to form bonding electrodes BOE. In an embodiment, the light emitting elements LE and the bonding electrodes BOE may be formed in a size and/or shape corresponding to the pixel electrodes PXE. For example, the light emitting elements LE and the bonding electrodes BOE may be formed to have an area corresponding to the area of the pixel electrodes PXE and have a planar shape that follows the planar shape of the pixel electrodes PXE. However, embodiments are not limited thereto, and the size and shape of the light emitting elements LE and the bonding electrodes BOE may be varied in different embodiments.

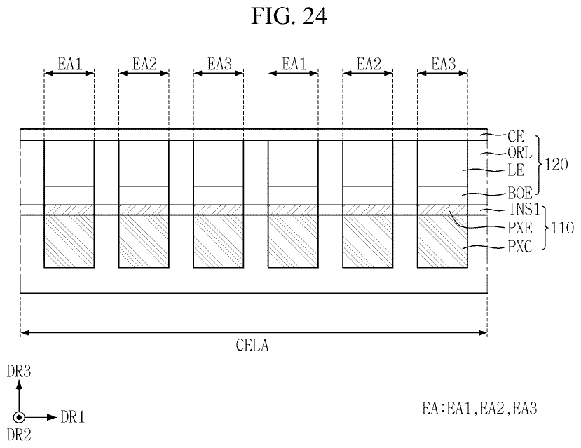

Referring to FIG. 24, subsequent processes to form the light emitting element layer 120 may be performed, including the process of forming the common electrode CE.

For example, as shown in FIG. 24, an organic layer ORL may be formed between the light emitting elements LE. Thereafter, the common electrode CE may be sequentially formed on the light emitting elements LE.

In an embodiment, in case of manufacturing a display panel including a light conversion layer and/or a color filter layer, a process of forming a light conversion layer and/or a color filter layer on the top (or upper surface) of the light emitting element layer 120 or inside the light emitting element layer 120 may be further performed.

In an embodiment, in case of manufacturing a display panel including a lens-type optical structure, a process of attaching and/or forming the lens-type optical structure or the like on the light emitting element layer 120 may be further performed.

Then, a module process or the like may be further performed to manufacture a display device including each display panel.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A wafer comprising:
a wafer substrate;
an epitaxial thin film disposed on the wafer substrate and including a first semiconductor layer, an active layer, a second semiconductor layer, and a third semiconductor layer; and
a plurality of markers formed on the epitaxial thin film and indicating a crystal orientation.

2. The wafer of claim 1, wherein the plurality of markers are made of a photosensitive polymer.

3. The wafer of claim 1, wherein the plurality of markers are disposed on a surface of the epitaxial thin film and spaced apart from neighboring markers by a first distance.

4. The wafer of claim 3, wherein the first distance is in a range of about 50 μm and about 300 μm.

5. The wafer of claim 1, wherein the plurality of markers are arranged in tens to hundreds per unit area of about 1 cm×1 cm of the epitaxial thin film.

6. The wafer of claim 1, wherein the plurality of markers have a thickness of about 500 nm to about 1 μm.

7. The wafer of claim 1, wherein each of the plurality of markers indicates a crystal orientation by a plurality of strokes and a contact point of each stroke.

8. The wafer of claim 7, wherein a length of each of the plurality of strokes ranges from about 500 nm to about 1 μm.

9. The wafer of claim 7, wherein the plurality of markers have a same shape.

10. The wafer of claim 7, wherein
the wafer substrate includes at least one of a flat zone and a notch, and
a crystal orientation indicated by the flat zone or the notch is consistent with a crystal orientation indicated by the plurality of markers.

11. A wafer comprising:
a wafer substrate;
an epitaxial thin film disposed on the wafer substrate and including a first semiconductor layer, an active layer, a second semiconductor layer, and a third semiconductor layer; and
a plurality of markers formed between the wafer substrate and the epitaxial thin film and indicating a crystal orientation.

12. A wafer die comprising:
a wafer substrate cut to a first size;
an epitaxial thin film disposed on the wafer substrate and including a first semiconductor layer, an active layer, a second semiconductor layer, and a third semiconductor layer; and
a plurality of markers formed on the epitaxial thin film and indicating a crystal orientation.

13. The wafer die of claim 12, wherein the first size is 1 cm×1 cm in width×height.

14. The wafer die of claim 12, wherein tens to hundreds of the plurality of markers are disposed on a surface of the epitaxial thin film.

15. The wafer die of claim 12, wherein each of the plurality of markers indicates a crystal orientation by a plurality of strokes and a contact point of each stroke.

16. A wafer die comprising:
a wafer substrate cut to a first size;
an epitaxial thin film disposed on the wafer substrate and including a first semiconductor layer, an active layer, a second semiconductor layer, and a third semiconductor layer; and
a plurality of markers formed between the wafer substrate and the epitaxial thin film and indicating a crystal orientation.

17. A method of manufacturing wafer die, the method comprising:
growing an epitaxial thin film including a first semiconductor layer, an active layer, a second semiconductor layer, and a third semiconductor layer on a wafer substrate to form an epitaxial wafer;
forming a plurality of markers indicating a crystal orientation on the epitaxial thin film; and
dividing the epitaxial wafer into a plurality of wafer dies,
wherein each of the wafer dies includes the plurality of markers.

18. The method of claim 17, wherein the forming of the plurality of markers indicating the crystal orientation includes forming a photoresist layer by uniformly applying a photosensitive polymer over the epitaxial thin film and the forming of the plurality of markers by selectively etching the photoresist layer using a mask pattern.

19. The method of claim 17, wherein the dividing the epitaxial wafer into a plurality of wafer dies includes dicing the epitaxial wafer to be divided into a plurality of wafer dies having a first size.

20. The method of claim 19, wherein the first size is 1 cm×1 cm in width×height.
